(19) United States
(12) Patent Application Publication
(10) Pub. No.: US 2008/0101016 A1
(43) Pub. Date: May 1, 2008

(54) AIRFLOW BAFFLE FOR A COMPUTER SYSTEM

(76) Inventors: Michael Brooks, Roseville, CA (US); James D. Hensley, Roseville, CA (US); Stephan Barsun, Davis, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/591,078

(22) Filed: Oct. 31, 2006

(51) Int. Cl. H05K 7/20; F16K 31/00

(52) U.S. Cl. 361/690; 361/692; 361/687; 361/718; 251/61; 174/16.1; 454/184; 312/236

(57) ABSTRACT

An airflow baffle apparatus for a forced-air cooled computer system is comprised of a linearly inflating airflow baffle bladder with a fixable surface and a topologically self-adjusting compliant surface. The linearly inflating airflow baffle bladder is couplable with the computer system. The fixable surface of the linearly inflating airflow baffle bladder is fixedly couplable to a first interior surface of the computer system. The topologically self-adjusting compliant surface of the linearly inflating airflow baffle bladder is couplable to an internal topology of the computer system in response to inflation of said linearly inflating airflow baffle bladder.

### TECHNICAL FIELD

Embodiments of the present technology relate to an airflow baffle for use in a computer system. More specifically, embodiments of the present technology relate to an inflatable airflow baffle for routing airflow and assisting in component attachment in a computer system.

### BACKGROUND

Most modern computer systems are compartmentalized by the enclosure of the system and the circuit boards inside the system. Such computer systems are typically air cooled by a fan that is pulling or pushing air through the enclosure of the computer system to cool hot components such as processors, memory, or other heat generating components. To maximize efficiency of fans and cooling, baffles are often used to help route airflow where it is needed for cooling.

Most baffles are typically made of rigid or semi rigid material such as sheet metal or hard plastic. Such baffles are typically built into the computer system and are permanently or removably clipped in, screwed on, or fastened in some way to prevent them from moving around easily. This adequately serves the purpose of routing cooling air. However, because these baffles are typically intended to be permanent fixtures in a single configuration, little or no flexibility is allowed if airflow needs change. For instance, in many cases when the configuration of how a system is assembled is changed (for example, memory is added to a previously empty slot) the internal topology will be changed enough that a different baffle will need to be installed. Thus, in a manufacturing setting a large variety of such baffles are typically required to match the variety of topologies created by differing configurations caused by adding or removing optional components to a single model of computer system, such as, for example, a particular model of a server.

One partial solution to this problem is the use of baffles with active or passive “doggie doors” which can be opened or closed based on the configuration of a computer system. For example in one type of passive doggie door, airflow swings the doggie door out of the way if no component is blocking the arc of the swing path. This allows air to flow through the opening created. In another example, installing a device, such as a power supply, may push or swing a doggie door out of the way so that the power supply gets airflow. Similarly, removing the power supply may cause the doggie door to fall back into place (shut) and close off airflow. Active doggie door baffles operate in a similar fashion but use a controllable actuator to open or shut the doggie door.

Adding doggie doors to a baffle provides some flexibility to use the baffle with a few different configurations of a computer system. However, current baffles with doggie doors suffer from some disadvantages, such as: being difficult to use or unusable with non-uniform component shapes and system topologies; limiting internal computer system designs to allow room for the arc of the swing path of a doggie door; and often being un-responsive to changes in thermal characteristics. Moreover, baffles with doggie doors still often need to be changed out when the internal topology of a computer system is altered either in manufacturing or as a result of a user modification.

Thus, as described, current baffles used to route airflow in air cooled computer systems suffer from several disadvantages that require numerous different baffles to be utilized to deal with differing internal topologies resulting from variations in configurations of computer systems.

### BRIEF DESCRIPTION OF THE DRAWINGS

The accompanying drawings, which are incorporated in and form a part of this specification, illustrate embodiments of the present technology for an airflow baffle for a computer system and, together with the description, serve to explain principles discussed below:

FIG. 1 is a sectional view of a computer system and an example airflow baffle apparatus with a linearly inflating airflow baffle bladder in an uninflated state, according to one embodiment of the present technology.

FIG. 2 is a sectional view of the computer system and the example airflow baffle apparatus with the linearly inflating airflow baffle bladder in a partially inflated state, according to one embodiment of the present technology.

FIG. 3 is a sectional view of the computer system and the example airflow baffle apparatus with the linearly inflating airflow baffle bladder in a fully inflated state, according to one embodiment of the present technology.

FIG. 4 is a plan view of the computer system and the example airflow baffle apparatus with the linearly inflating airflow baffle bladder in a fully inflated state, according to one embodiment of the present technology.

FIG. 5 is a perspective view of a computer system and the example airflow baffle apparatus with the linearly inflating airflow baffle bladder in a fully inflated state, according to one embodiment of the present technology.

FIG. 6 is a flow diagram of a method for controlling airflow in a computer system, according to one embodiment of the present technology.

The drawings referred to in this description should not be understood as being drawn to scale unless specifically noted.

### DETAILED DESCRIPTION

Reference will now be made in detail to embodiments of the present technology for an airflow baffle for a computer system, examples of which are illustrated in the accompanying drawings. While the present technology is described in conjunction with various embodiments, it will be understood that they are not intended to limit the present technology to these embodiments. On the contrary, the presented technology is intended to cover alternatives, modifications and equivalents, which may be included within the spirit and scope the various embodiments as defined by the appended claims. Furthermore, in the following detailed description, numerous specific details are set forth in order to provide a thorough understanding of the present technology. However, the present technology may be practiced without these specific details. In other instances, well known methods, procedures, components, and circuits have not been described in detail as not to unnecessarily obscure aspects of the present technology.

### General Description of the Present Technology for an Airflow Baffle for a Computer System

### Overview

The present technology for an airflow baffle for a computer system demonstrates an airflow baffle apparatus with a linearly inflating airflow baffle bladder, which can conform to the interior topology of a variety of computer systems. As will be seen, this airflow baffle apparatus is both self-sealing and self-adjusting in response to being inflated. The present technology provides the advantage of reduced assembly time for installing a baffle. The present technology also provides the advantage of a single airflow baffle which is useable with a variety of internal computer system configurations and topologies which previously would have utilized numerous custom formed baffles.

The following description of an airflow baffle apparatus for a computer system will be presented in two parts. The first part will describe the structure with reference to an example airflow baffle apparatus, according to one embodiment of the present technology. The second part will describe an example method for controlling airflow in a computer system, according to one embodiment of the present technology.

### Example Airflow Baffle Apparatus

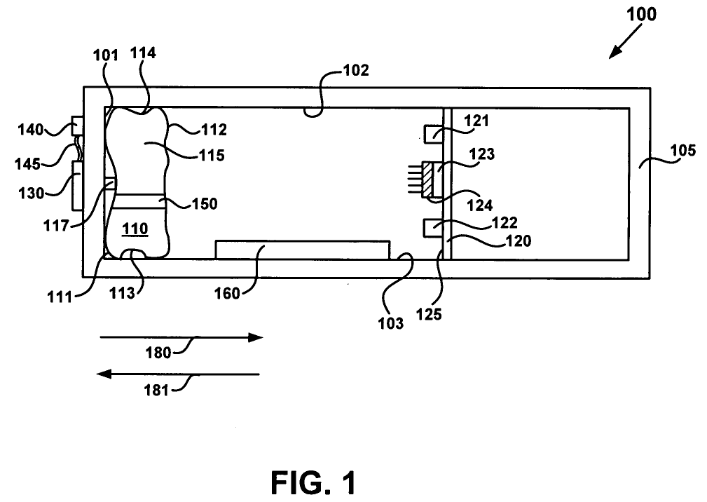

FIG. 1 is a sectional view of a computer system 100 and an example airflow baffle apparatus with a linearly inflating airflow baffle bladder 110 in an uninflated state, according to one embodiment of the present technology. Computer system 100 is comprised of a case 105 and a circuit board 120. As shown in FIG. 1, circuit board 120 is a mid-plane circuit board with a surface 125 to which a variety of circuit boards and/or components may be coupled. As shown in FIG. 1, a processor 123 and heat sink 124, a memory 121, and power supply 122 are coupled to surface 125. Additionally, as shown in FIG. 1, the example airflow baffle apparatus is comprised of: a linearly inflating airflow baffle bladder 110, an optional controllable bladder inflation mechanism 130, an optional thermally reactive dynamic inflation control module 140, an optional linear bladder retraction mechanism 150, and an optional linear inflation guide 160.

Linearly inflating airflow baffle bladder 110, in one embodiment, is comprised of an inflatable material with a low permeability. In one embodiment, linearly inflating airflow baffle bladder 110 is configured for being inflated with a gaseous substance, such as, but not limited to: air, helium, nitrogen, or carbon dioxide. In another embodiment, linearly inflating airflow baffle bladder 110 is configured for being inflated with a liquid substance, such as, for example, water. In another embodiment, linearly inflating airflow baffle bladder 110 is configured for being inflated with a phase changing substance, such as, for example, expanding polyurethane foam, closed cell foam, or resilient open cell foam.

In various embodiments linearly inflating airflow baffle bladder 110 may be constructed of plastic, rubber, metal, metalized membrane, Mylar, cloth, or other inflatable material or combination of materials suitable for containing the inflation substance that bladder 110 is intended to be inflated with. In some embodiments, all or a portion of the inflatable material is resilient, and stretches in response to inflation. In other embodiments, the material is not resilient, but instead linearly inflating airflow baffle bladder 110 simply expands until expansion is limited by either the designed construction of the inflated shape and size of linearly inflating airflow baffle bladder 110 or else by contact with an object which a surface of linearly inflating airflow baffle bladder 110 encounters as a result of expansion during inflation. In some embodiments, as will be described below, linearly inflating airflow baffle bladder 110 is purposefully or unintentionally placed into proximity or contact with components of a computer system which can get very hot. Some examples of such hot components are processor 123 and heat sink 124. In such embodiments, a portion of or all of linearly inflating airflow baffle bladder 110 is made of a heat resistant material to prevent damage to the bladder from contact with a hot component.

Linearly inflating airflow baffle bladder 110 is configured for inflating primarily in a linear direction, such as direction 180, in response to being inflated. Once inflated, either partially or fully, linearly inflating airflow baffle bladder 110 is used in one embodiment for forming a baffle for defining an airflow path for cooling air within computer system 100. As will be seen, in one embodiment linearly inflating airflow baffle bladder 110 can also be used as a component attachment system within a computer system.

Linearly inflating airflow baffle bladder 110, as shown in FIG. 1, comprises a fixable surface 111 which is fixedly couplable to an interior surface 101 of case 105 of computer system 100. In one embodiment, fixable surface 111 is fixedly coupled, such as with an adhesive, to interior surface 101. In one embodiment, the coupling between fixable surface 111 and interior surface 101 occurs as a result of the expansion of linearly inflating airflow baffle bladder 110 during inflation. In one embodiment, fixable surface 111 is also configured with an optional input mechanism 117, such as a nozzle, which is configured for coupling with an inflation mechanism to receive an inflation substance which will inflate linearly inflating airflow baffle bladder 110.

Linearly inflating airflow baffle bladder 110 also comprises a topologically self-adjusting compliant surface 112. Topologically self-adjusting compliant surface 112 is compliably couplable to an internal topology of computer system 100. Topologically self-adjusting compliant surface 112 is configured for self-adjusting to an internal topology of computer system 100 in response to inflation of linearly inflating airflow baffle bladder 110. Topologically self-adjusting compliant surface 112 is configured to move generally in a linear direction, such as direction 180, relative to fixable surface 111 in response to inflation.

The self-adjusting is accomplished in one embodiment by constructing topologically self-adjusting compliant surface 112 with a compliant material or a compliant construction technique, which allows topologically self-adjusting compliant surface 112 to compliably conform around object shapes encountered as a result of expansion of linearly inflating airflow baffle bladder 110 during inflation. This is accomplished in one embodiment by utilizing a resilient material either to construct topologically self-adjusting compliant surface 112 or as a facing on topologically self-adjusting compliant surface 112. Such a resilient material allows a portion of topologically self-adjusting compliant surface 112 to self-adjust to the shape of an object encountered during inflation of linearly inflating airflow baffle bladder 110. An example of such a resilient material is rubber.

In another embodiment, the self-adjusting is accomplished by utilizing an abundance of material on topologically self-adjusting compliant surface 112, such that a portion of topologically self-adjusting compliant surface 112 can self-adjust to the shape of an encountered object while other portions of topologically self-adjusting compliant surface 112 continue expanding as a result of continued inflation of linearly inflating airflow baffle bladder 110. An example of adding an utilizing an abundance of material is the constructing of topologically self-adjusting compliant surface 112 with folds of material, such as pleats, to allow for adjustment to encountered objects.

Linearly inflating airflow baffle bladder 110 also comprises a first airflow baffle wall forming surface 115 which is configured for forming a first side of a wall of a baffle as a result of inflation of linearly inflating airflow baffle bladder 110. In one embodiment, first airflow baffle wall forming surface 115 is generally planar or slightly convex when linearly inflating airflow baffle bladder 110 is inflated. However, some irregularities, such as wrinkles or a slight waviness are to be expected depending upon the amount of inflation of linearly inflating airflow baffle bladder 110 and the substance used for inflation. In one embodiment, first airflow baffle wall forming surface 115 is comprised of material that is folded, such as in an accordion fashion, to facilitate easy expansion in a linear direction, such as direction 180, in response to inflation of linearly inflating airflow baffle bladder 110. Following partial or full inflation of linearly inflating airflow baffle bladder 110, first airflow baffle wall forming surface 115 provides a baffle wall which cooling air of computer system 100 must flow around. The baffle wall also provides structural stability for the baffle formed by inflating linearly inflating airflow baffle bladder 110.

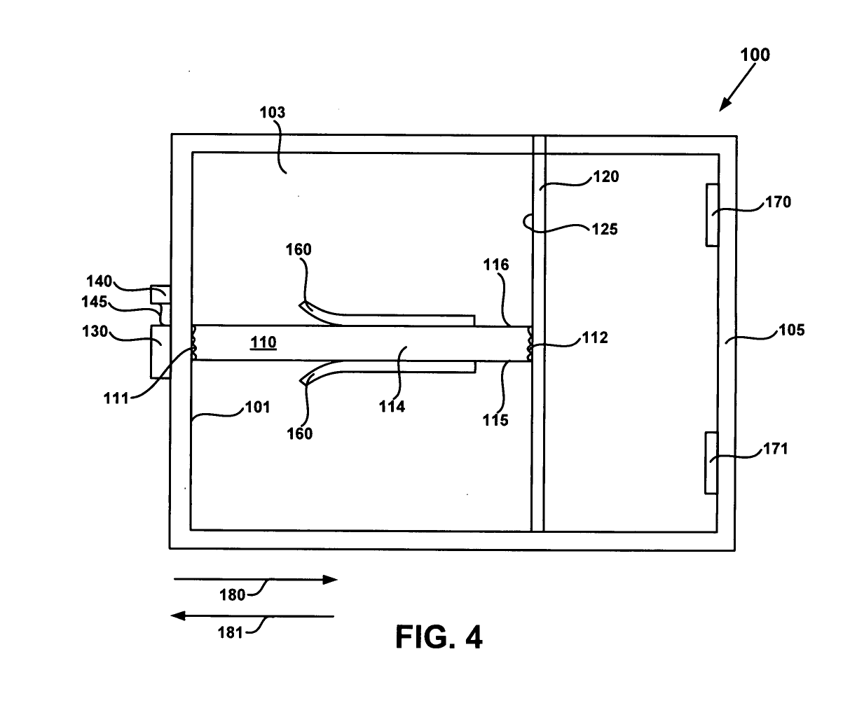

In one embodiment, linearly inflating airflow baffle bladder 110 also comprises a second airflow baffle wall forming surface 116 (visible in FIG. 4) which is opposite first airflow baffle wall forming surface 115, and is configured for forming a second side of a wall of a baffle as a result of inflation of linearly inflating airflow baffle bladder 110. In one embodiment, second airflow baffle wall forming surface 116 is generally planar or slightly convex when linearly inflating airflow baffle bladder 110 is inflated. However, some irregularities, such as wrinkles or a slight waviness are to be expected depending upon the amount of inflation of linearly inflating airflow baffle bladder 110 and the substance used for inflation. In one embodiment, second airflow baffle wall forming surface 116 is comprised of material that is folded, such as in an accordion fashion, to facilitate easy expansion in a linear direction, such as direction 180, in response to inflation of linearly inflating airflow baffle bladder 110. Following partial or full inflation of linearly inflating airflow baffle bladder 110, second airflow baffle wall forming surface 116 provides a baffle wall which cooling air of computer system 100 must flow around. The baffle wall also provides structural stability for the baffle formed by inflating linearly inflating airflow baffle bladder 110.

In one embodiment, linearly inflating airflow baffle bladder 110 also comprises a first air sealing surface 113 configured for forming a first air seal with an interior surface of case 105, such as interior surface 103. This first air seal is formed as a result of a slight expansion of first air sealing surface 113, into contact with interior surface 103. This slight expansion occurs as a result of inflatable bladder being partially or fully inflated. It is appreciated that this air seal is not required to be a perfect air seal and that in some embodiments, small air gaps may exist between first air sealing surface 113 and interior surface 103. Such small air gaps will not have a significant effect on the cooling air routing function performed by linearly inflating airflow baffle bladder 110. The length of this first air seal increases as first air sealing surface 113 expands in a linear direction, such as direction 180, as a result of linearly inflating airflow baffle bladder 110 being inflated. Additionally, it is appreciated that the friction of contact between first air sealing surface 113 and interior surface 103 provides structural stability for the air baffle formed by inflating linearly inflating airflow baffle bladder 110.

In one embodiment, linearly inflating airflow baffle bladder 110 also comprises a second air sealing surface 114 configured for forming a second air seal with an interior surface of case 105, such as interior surface 102. This second air seal is formed as a result of a slight expansion of second air sealing surface 114, into contact with interior surface 102. This slight expansion occurs as a result of inflatable bladder being partially or fully inflated. It is appreciated that this air seal is not required to be a perfect air seal and that in some embodiments, small air gaps may exist between second air sealing surface 114 and interior surface 102. Such small air gaps will not have a significant effect on the cooling air routing function performed by linearly inflating airflow baffle bladder 110. The length of this second air seal increases as second air sealing surface 114 expands in a linear direction, such as direction 180, as a result of linearly inflating airflow baffle bladder 110 being inflated. Additionally, it is appreciated that the friction of contact between second air sealing surface 114 and interior surface 102 provides structural stability for the air baffle formed by inflating linearly inflating airflow baffle bladder 110.

In one embodiment, the airflow baffle apparatus is also comprised of an optional linear inflation guide 160. Linear inflation guide 160 is configured to couple with linearly inflating airflow baffle bladder 110, for example, during inflation of linearly inflating airflow baffle bladder 110. In one embodiment, linear inflation guide 160 guides an expanding portion of linearly inflating airflow baffle bladder 110 along a pre-selected path in a linear direction, such as direction 180, in response to inflation of linearly inflating airflow baffle bladder 110. This is especially useful, for example, in a situation where linearly inflating airflow baffle bladder 110 is configured to expand over a long linear distance, for example greater than 20 centimeters, in response to being inflated.

In one embodiment, optional linear inflation guide 160 is utilized as a bladder shroud mechanism which is configured for coupling with linearly inflating airflow baffle bladder 110 to control a direction of expansion of linearly inflating airflow baffle bladder 110. For example, in one embodiment, linear inflation guide 160 is utilized as a bladder shroud mechanism to prevent linearly inflating airflow baffle bladder 110 from expanding away from a pre-defined path into an area occupied (or potentially occupied) by in internal component which may be damaged by linearly inflating airflow baffle bladder 110 or else which may cause damage to linearly inflating airflow baffle bladder 110. Thus, when utilized as a bladder shroud mechanism, linear inflation guide 160 prevents damage to an internal component of computer system 100 and/or to linearly inflating airflow baffle bladder 110, which may occur as a result of expansion into an internal component of computer system 100 while linearly inflating airflow baffle bladder 110 is being inflated or deflated.

In one embodiment, the airflow baffle apparatus is also comprised of an optional controllable bladder inflation mechanism 130 that is configured for coupling with and inflating linearly inflating airflow baffle bladder 110. In one embodiment, for example, controllable bladder inflation mechanism 130 is coupled with optional inflation substance receiving input connector 117. In one embodiment, controllable bladder inflation mechanism 130 comprises an inflation fan, such as a computer fan, which blows air into an opening, such as optional inflation substance receiving input connector 117, to inflate linearly inflating airflow baffle bladder 110. In another embodiment, controllable bladder inflation mechanism 130 comprises a pump, such as an air pump for pumping air into linearly inflating airflow baffle bladder 110 for the purpose of inflating linearly inflating airflow baffle bladder 110. In other embodiments, controllable bladder inflation mechanism 130 comprises a pump for pumping a liquid, gas, or foam into linearly inflating airflow baffle bladder 110 from a reservoir in or attached to controllable bladder inflation mechanism 130. In some embodiments, such as where a detachable one time use inflation mechanism is used for inflation of linearly inflating airflow baffle bladder 110, controllable bladder inflation mechanism 130 is not required. An air hose is an example of a one time use inflation mechanism. Similarly, a hose coupled to a supply of gas, foam, or liquid, could also comprise a one time use inflation mechanism.

In one embodiment, controllable bladder inflation mechanism 130 can be operated, for example in reverse, to serve as a controllable bladder deflation mechanism for deflating linearly inflating airflow baffle bladder 110 after it has been inflated. In other embodiments (not shown) an optional controllable bladder deflation mechanism separate from controllable bladder inflation mechanism 130 is utilized to deflate linearly inflating airflow baffle bladder 110.

In one embodiment, the air baffle apparatus also comprises an optional thermally reactive dynamic inflation control module 140 configured for dynamically controlling an amount of inflation of linearly inflating airflow baffle bladder 110 in response to a thermal characteristic of computer system 100. For example, in one embodiment, thermally reactive dynamic inflation control module 140 causes controllable bladder inflation mechanism 130 to increase the inflation of linearly inflating airflow baffle bladder 110 in response to an increase in an internal temperature of computer system 100. For example, as shown in FIG. 1, increasing the inflation of linearly inflating airflow baffle bladder 110 causes more cooling air to be routed over processor 123 and heat sink 124. This has an additional effect of noise reduction by reducing noise generated by cooling fans. This is because in most systems cooling fans would have to be run at a higher speed to achieve a similar increase in cooling air volume across heat sink 124 as was achieved by increasing the inflation of linearly inflating airflow baffle bladder 124.

This improves the cooling of processor 123. In another embodiment, thermally reactive dynamic inflation control module 140 causes controllable bladder inflation mechanism 130 to act as a controllable bladder deflation mechanism and partially deflate linearly inflating airflow baffle bladder 110 in response to sensing a lower internal temperature of computer system 100. In one embodiment, thermally reactive dynamic inflation control module 140 is external to controllable bladder inflation mechanism 130 and the two are coupled via a coupling 145. In another embodiment, thermally reactive dynamic inflation control module 140 an integral portion of controllable bladder inflation mechanism 130.

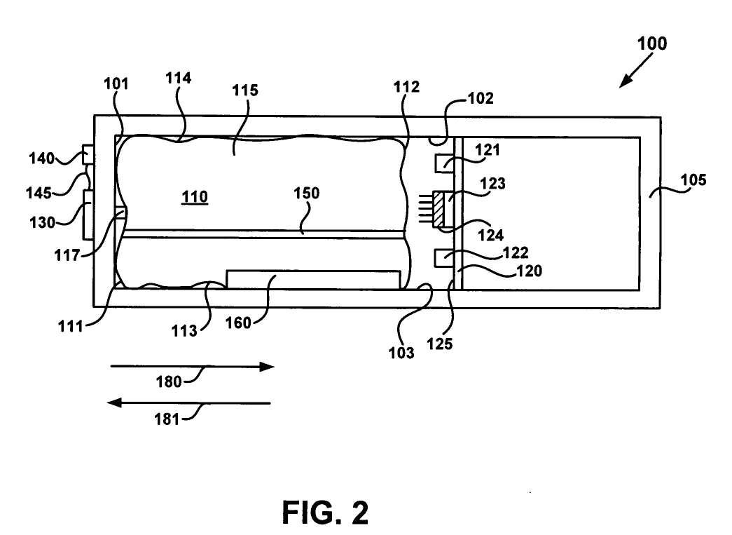

In one embodiment, the air baffle apparatus also comprises an optional linear bladder retraction mechanism 150 which assists in the retraction and/or stowing of linearly inflating airflow baffle bladder 110 in response to linearly inflating airflow baffle bladder 110 being deflated. As shown in FIG. 1, linear bladder retraction mechanism 150 is an elastic band which surrounds linearly inflating airflow baffle bladder 110. Also as shown in FIG. 1 (and FIG. 2), linear bladder retraction mechanism 150 expands, or stretches, in direction 180 in response to inflation of linearly inflating airflow baffle bladder 110, thus building up a retractive force. When linearly inflating airflow baffle bladder 110 is later deflated, the retractive force of linear bladder retraction mechanism 150 responsively retracts linearly inflating airflow baffle bladder 110 in direction 181. Though linear bladder retraction mechanism 150 is shown as a passive external elastic band, it is appreciated that in other embodiments linear bladder retraction mechanism 150 can comprise an active retraction mechanism, other external mechanisms such as spring, or an internal retraction mechanism such as a spring or elastic band. In an embodiment where linearly inflating airflow baffle bladder 110 is not designed to be deflated, linear bladder retraction mechanism 150 is not necessary. Likewise, in some embodiments, running controllable bladder inflation mechanism 130 in reverse may cause linearly inflating airflow baffle bladder 110 to sufficiently retract in response to deflation such that linear bladder retraction mechanism 150 is not necessary.

FIG. 2 is a sectional view of computer system 100 and the example airflow baffle apparatus with linearly inflating airflow baffle bladder 110 in a partially inflated state, according to one embodiment of the present technology. In FIG. 2, like numbered components to FIG. 1 are the same as previously described in FIG. 1. FIG. 2 demonstrates the expansion of linearly inflating airflow baffle bladder 110 to form an airflow baffle in response to being inflated. FIG. 2 also demonstrates the function of optional linear inflation guide 160 to guide the linear expansion of linearly inflating airflow baffle bladder 110 in direction 180. FIG. 2 additionally demonstrates the stretching of linear bladder retraction mechanism 150 in response to the inflation of linearly inflating airflow baffle bladder 110.

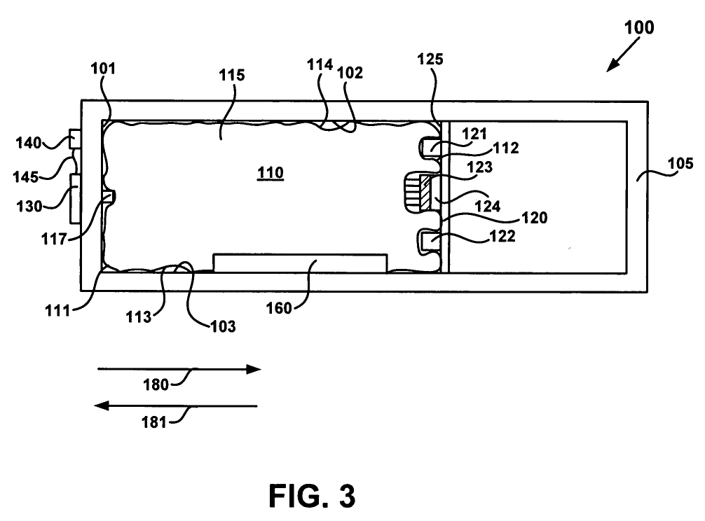

FIG. 3 is a sectional view of computer system 100 and the example airflow baffle apparatus with linearly inflating airflow baffle bladder 110 in a fully inflated state, according to one embodiment of the present technology. In FIG. 3, like numbered components are the same as described in FIG. 1 and FIG. 2. FIG. 3 demonstrates an embodiment of the airflow baffle apparatus which does not utilize external linear bladder retraction mechanism 150. FIG. 3 also demonstrates topologically self-adjusting compliant surface 112 conforming to and compressing against surface 125, memory 121, power supply 122, processor 123, and heat sink 124. As shown, topologically self-adjusting compliant surface 112 is compliant enough to self-adjust generally to the shapes of components 121, 122, 123, and 124, and surface 125 in response to inflation. However, topologically self-adjusting compliant surface 112 is not compliant enough to fit into the small spaces between the fins of heat sink 124. This leaves a passage for airflow through the fins of heat sink 124, thus concentrating cooling airflow of computer system 100 through heat sink 124 and improving the cooling of processor 123.

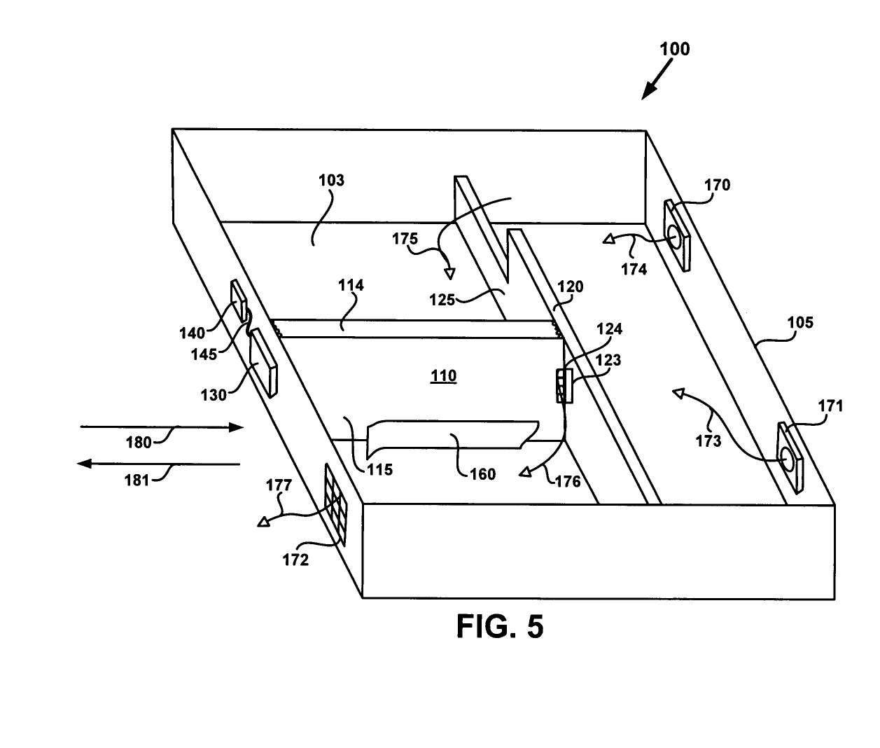

FIG. 4 is a plan view of computer system 100 and the example airflow baffle apparatus with linearly inflating airflow baffle bladder 110 in a fully inflated state, according to one embodiment of the present technology. In FIG. 4, like numbered components are the same as described in FIG. 1, FIG. 2, and FIG. 3. In FIG. 4, second airflow baffle wall forming surface 116 is visible. Additionally, in FIG. 4, cooling fans 170 and 171 are visible. In the embodiments shown in FIG. 4 and FIG. 5, cooling fans 170 and 171 are used to force cooling air into computer system 100.

FIG. 5 is a perspective view of computer system 100 and the example airflow baffle apparatus with linearly inflating airflow baffle bladder 110 in a fully inflated state, according to one embodiment of the present technology. In FIG. 5, like numbered components are the same as described in FIG. 1, FIG. 2, FIG. 3, and FIG. 4. In FIG. 5, like in FIG. 3 linearly inflating airflow baffle bladder 110 is shown without external linear bladder retraction mechanism 150. FIG. 5, shows an airflow path that is created with fully inflated linearly inflating airflow baffle bladder 110. For example, cooling air enters computer system 100 via cooling fans 170 and 171. Cooling air is then forced on the path shown by arrows 173, 174, 175, 176, and 177. Due to the positioning of linearly inflating airflow baffle bladder 110 against surface 125 and surrounding heat sink 124, cooling air is forced through heat sink 124, as shown by arrow 176, before exiting from computer case 105 via outlet 172, as shown by arrow 177.

Additionally, FIG. 5 demonstrates a different topology of surface 125 of circuit board 120. Memory 121 and power supply 122 are not present on surface 125. The absence of components 121 and 122 is representative of a typical configuration change that can occur with a computer system during the manufacturing process due to a design change or due to a different customer requirement for a particular computer system 100. As shown in FIG. 5, topologically self-adjusting compliant surface 112 of linearly inflating airflow baffle bladder 110 has self-adjusted to comply with the changed internal topology of computer system 100 caused by omitting components 121 and 122 from circuit board 120. Likewise, it is appreciated in an embodiment where an additional component is added to circuit board 120, that topologically self-adjusting compliant surface 112 will self-adjust to conform to the topology of the additional component if the additional component is contacted by topologically self-adjusting compliant surface 112 during the inflation of linearly inflating airflow baffle bladder 110.

In one embodiment, linearly inflating airflow baffle bladder 110 is utilized as a component attachment apparatus for a computer system. In one such embodiment, linearly inflating airflow baffle bladder 110 is configured for expanding linearly to fill a void within a computer system 100 in response to being inflated into an inflated state. As previously described this linear expansion is useful for displacing and controlling the routing of airflow. This linear expansion allows more design flexibility, as no swing arc path must be designed around or left empty of components. Moreover, this linear expansion is also useful for applying a linearly acting force to fixedly hold a component, such as a heat sink or a processor, in a desired place on a circuit board.

For example, as shown in FIG. 3 and FIG. 5, linearly inflating airflow baffle bladder 110 works as a component attachment apparatus by expanding linearly between an interior surface of computer system 110, such as interior surface 101, and a component, such as heat sink 124. As shown in FIGS. 3 and 5, this inflation couples fixable surface 111 to interior surface 101 and also causes topologically self-adjusting compliant surface 112 to self-adjust to the internal topology of computer system 100, such that topologically self-adjusting compliant surface 112 compresses heat sink 124 against processor 123. In such an embodiment, surface 112 acts as a component attaching topologically self-adjusting compliant surface. The linear force of the inflation as applied through topologically self-adjusting compliant surface 112 causes heat sink 124 to be fixedly coupled to processor 123. This linear force also holds processor 123 in place, sandwiched between circuit board 120 and heat sink 124. It is appreciated that topologically self-adjusting compliant surface 112 of inflatable air flow baffle bladder 110 can be used to fixedly hold a variety of additional components and types of components in place within a computer system.

As shown in FIGS. 3 and 5, in an embodiment where linearly inflating airflow baffle bladder 110 is used as a component attaching apparatus, linearly inflating airflow baffle bladder 110 is comprised of a first airflow baffle wall forming surface 115, a second airflow baffle wall forming surface 116, a first air sealing surface 113 and a second air sealing surface 114. In response to inflating of linearly inflating airflow baffle bladder 110, first airflow baffle wall forming surface 115 is configured for forming a first side of a wall (previously described) of a baffle for routing cooling air of computer system 100 through heat sink 124. Likewise, in response to inflating of linearly inflating airflow baffle bladder 110, second airflow baffle wall forming surface 116 is configured for forming a second side of the wall (previously described) of the baffle formed by linearly inflating airflow baffle bladder 110 in an inflated state. Similarly, in response to inflating of linearly inflating airflow baffle bladder 110, first air sealing surface 113 is configured for forming a first air seal (previously described) with interior surface 103 of case 105 of computer system 100. Likewise, in response to the inflation of linearly inflating airflow baffle bladder 110, second air sealing surface 114 is configured for forming a second air seal (previously described) with interior surface 102 of case 105 of computer system 100.

In one embodiment, where linearly inflating airflow baffle bladder 110 is used as part of a component attaching apparatus, the apparatus is also comprised of an controllable bladder inflation mechanism 130 (previously described) configured for coupling with and inflating linearly inflating airflow baffle bladder 110. In other embodiments, linearly inflating airflow baffle bladder 110 is inflated with a detachable one time use inflation mechanism (not shown) and thus controllable bladder inflation mechanism 130 is not necessary.

### Method for Controlling Airflow in a Computer System

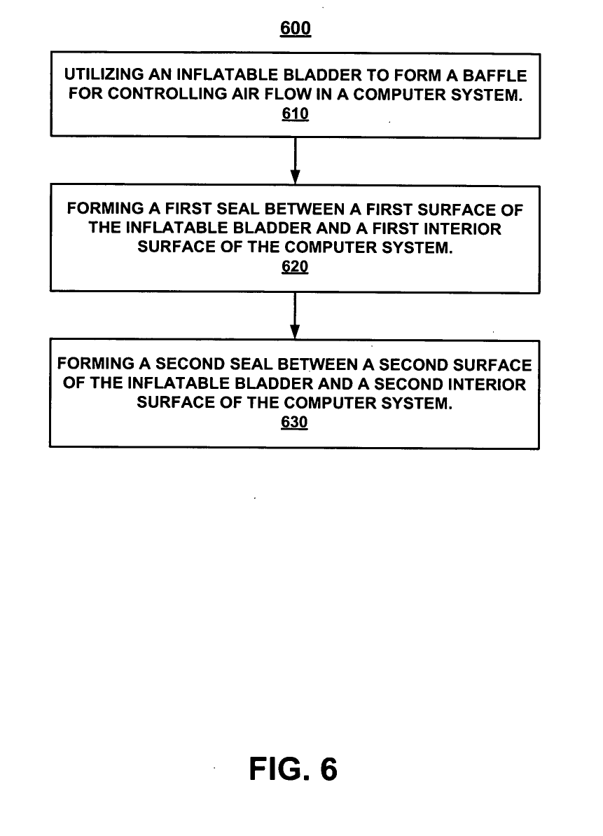

The following discussion sets forth in detail the operation of present technology through description of example embodiments. With reference to FIG. 6, flow diagram 600 illustrates example steps used by various embodiments of the present technology. Although specific steps are disclosed in flow diagram 600, such steps are examples. That is, embodiments are well suited to performing various other steps or variations of the steps recited in flow diagram 600. It is appreciated that the steps in flow diagram 600 may be performed in an order different than presented, and that not all of the steps in flow diagram 600 may be performed.

FIG. 6 is a flow diagram of a method for controlling airflow in a computer system, such as computer system 100, according to one embodiment of the present technology.

At 610 of flow diagram 600, in one embodiment, the method utilizes an inflatable bladder to form a baffle for controlling airflow in a computer system. Linearly inflating airflow baffle bladder 110, described above, is one example of such an inflatable bladder. With reference to FIG. 1 and FIG. 2 in one embodiment, utilizing linearly inflating airflow baffle bladder 110 comprises inflating linearly inflating airflow baffle bladder 110 such that topologically self-adjusting compliant surface 112 moves in a primarily linear path (shown by direction 180) away from fixable surface 111. As shown by FIG. 1 and FIG. 2, fixed surfaced 111 is coupled to interior surface 111 of case 105 of computer system 100. The expansion in direction 180 is shown by the change in the size of linearly inflating airflow baffle bladder 110 between FIG. 1 and FIG. 2.

With reference to FIG. 1, FIG. 2, and FIG. 3, in one embodiment utilizing linearly inflating airflow baffle bladder 110 also comprises altering a position of topologically self-adjusting compliant surface 112 relative to fixable surface 111 by changing an inflation level of bladder 110 in response to a thermal characteristic of computer system 100. This altering adjusts the airflow in computer system 100 by altering the size and configuration of the baffle formed by linearly inflating airflow baffle bladder 110. The results of altering the position of topologically self-adjusting compliant surface 112 relative to fixable surface 111 are seen by the difference in the location of topologically self-adjusting compliant surface 112 from FIG. 1 to FIG. 2, and from FIG. 2 to FIG. 3.

For example, assuming FIG. 2 as a starting point, in one embodiment, thermally reactive dynamic inflation control module 140 senses an increase in the internal temperature of computer case 105. In response to this change in thermal characteristic, thermally reactive dynamic inflation control module 140 sends a control signal via coupling 145 to controllable bladder inflation mechanism 130. Controllable bladder inflation mechanism 130 then further inflates linearly inflating airflow baffle bladder 110 such that topologically self-adjusting compliant surface 112 moves in linear direction 180 to increase the length of the baffle formed by linearly inflating airflow baffle bladder 110. This changes the position of compliant surface from the position shown in FIG. 2 to the position and configuration shown in FIG. 3. Similarly, in one embodiment, in response to sensing a decreased internal temperature of computer system 100 thermally reactive dynamic inflation control module 140 controls controllable bladder inflation mechanism 130 to deflate linearly inflating airflow baffle bladder 110 linearly in direction 181 from the configuration shown in FIG. 3 back to the configuration shown in FIG. 2.

At 620 of flow diagram 600, in one embodiment, the method forms a first seal between a first surface the inflatable bladder and a first interior surface of the computer system. With reference to FIG. 1 and FIG. 2, the forming of this first seal is demonstrated by the self-sealing action of seal forming surface 112 as it forms a seal with interior surface 103 in response to inflation of linearly inflating airflow baffle bladder 110. As previously described, it is not required that this seal is perfect, and there may be some small gaps in the seal. Additionally, it is appreciated that although interior surface 103 is shown as substantially planar, this is not required. For example, in one embodiment, air sealing surface 113 is capable of self-sealing to surface 103 even when surface 103 contains some irregularities, such as small mounting hardware (nuts, bolts, and the like), small gaps, holes, and the like, as are often found on an interior surface of a computer case.

At 630 of flow diagram 600, in one embodiment, the method forms a second seal between a second surface of the inflatable bladder and a second interior surface of the computer system. With reference to FIG. 1 and FIG. 2, the forming of this second seal is demonstrated by the self-sealing action of seal forming surface 114 as it forms a seal with interior surface 102 in response to inflation of linearly inflating airflow baffle bladder 110. As previously described, it is not required that this seal is perfect, and there may be some small gaps in the seal. Additionally, it is appreciated that although interior surface 102 is shown as substantially planar, this is not required. For example, in one embodiment, air sealing surface 114 is capable of self-sealing to surface 102 even when surface 102 contains some irregularities, such as small mounting hardware (nuts, bolts, and the like), small gaps, holes, and the like, as are often found on an interior surface of a computer case.

In one embodiment, the method for controlling airflow in a computer system also comprises contouring a compliant surface of the inflatable bladder against a portion of an internal topology of the computer system. For example, as shown in FIG. 3, topologically self-adjusting compliant surface 112 of linearly inflating airflow baffle bladder 110 self-adjusts to compliably couple with and contour around components 121, 122, 123, and 124 on printed circuit board 120. Additionally, topologically self-adjusting compliant surface 112 also self-adjusts to compliably couple with and contour to a portion of surface 125 of printed circuit board 120. Each of these components (121, 122, 123, and 124), circuit board 120, and surface 125 form a portion of the internal topology of computer system 100. This self-adjusting contouring is performed automatically by linearly inflating airflow baffle bladder 110 as a result of inflation and linear expansion in direction 180 until the components (121, 122, 123, and 124) are contacted with and compliably contoured around by complaint surface 112. As shown in FIG. 3, topologically self-adjusting compliant surface 112 compresses against the components (121, 122, 123, and 124) and expands to conform around them in response to continued inflation of linearly inflating airflow baffle bladder 110.

As can be seen in FIG. 3 and additionally in FIG. 5, in one embodiment the contouring of topologically self-adjusting compliant surface 112 against a portion of an interior topology, such as components 123 and 124, on printed circuit board 120, forms an airflow seal around the components (123 and 124) and with surface 125 of printed circuit board 120. This is useful, as demonstrated by FIG. 3 and FIG. 5, for forming an airflow seal around a component such as heat sink 124 to define an airflow path which forces cooling airflow (shown by arrow 176 in FIG. 5) to flow either exclusively or at an increased rate through heat sink 124. This results in increased cooling to processor 123 to which heat sink 124 is coupled.

Additionally, as can be seen in FIG. 3 and in FIG. 5, in one embodiment the contouring of topologically self-adjusting compliant surface 112 against a portion of an interior topology, such as heat sink 124 and processor 123, on printed circuit board 120 also linearly compresses topologically self-adjusting compliant surface 112 against heat sink 124 to cause heat sink 124 to be fixedly coupled a processor 123. This compressive linear force also fixedly couples processor 123 in place, sandwiched between circuit board 120 and heat sink 124. In one such embodiment, this compressing force allows topologically self-adjusting compliant surface 112 to act as a component attaching topologically self-adjusting compliant surface which can be used in a variety of scenarios and with a wide variety of internal topologies to fixedly attach components or securely hold components in place. This provides the advantage of requiring less attaching hardware such as clamps, clasps, adhesives, screws, bolt, and the like to hold a component, such as heat sink 124 or processor 123, in place on a printed circuit board. In one embodiment, compressing complaint surface 112 against a component (in response to inflating linearly inflating airflow baffle bladder 110) also speeds assembly time in manufacturing, by automating the process of attaching and holding a variety of components in place as well as automating the process of installing and securing an airflow baffle.

Although the subject matter of the present technology has been described in a language specific to structural features and/or methodological acts, it is to be understood that the subject matter defined in the appended claims is not necessarily limited to the specific features or acts described above. Rather, the specific features and acts described above are disclosed as example forms of implementing the claims.

1. An airflow baffle apparatus for a forced-air cooled computer system, said apparatus comprising:
a linearly inflating airflow baffle bladder couplable with said computer system;
a fixable surface of said linearly inflating airflow baffle bladder, said fixable surface fixedly couplable to a first interior surface of said computer system; and
a topologically self-adjusting compliant surface of said linearly inflating airflow baffle bladder, said topologically self-adjusting compliant surface compliably couplable to an internal topology of said computer system in response to inflation of said linearly inflating airflow baffle bladder.

2. The apparatus of claim 1, wherein said linearly inflating airflow baffle bladder further comprises:
a first airflow baffle wall forming surface configured for forming a first side of a wall of said linearly inflating airflow baffle bladder;
a second airflow baffle wall forming surface configured for forming a second side of said wall;
a first air sealing surface couplable with a second interior surface of said computer system for forming a first air seal with said second interior surface of said computer system; and
a second air sealing surface couplable with a third interior surface of said computer system for forming a second air seal with said third interior surface of said computer system.

3. The apparatus of claim 1, further comprising:
a linear inflation guide couplable with said linearly inflating airflow baffle bladder.

4. The apparatus of claim 1, further comprising:
a controllable bladder inflation mechanism configured for coupling with and said linearly inflating airflow baffle bladder.

5. The apparatus of claim 4, wherein said controllable bladder inflation mechanism comprises:
an inflation fan configured for coupling with said linearly inflating airflow baffle bladder.

6. The apparatus of claim 4, wherein said controllable bladder inflation mechanism further comprises:
a thermally reactive dynamic inflation control module configured for dynamically controlling an amount of inflation of said linearly inflating airflow baffle bladder in response to a thermal characteristic of said computer system.

7. The apparatus of claim 1, wherein said linearly inflating airflow baffle bladder further comprises:
an inflation substance receiving input connector configured for coupling with a controllable bladder inflation mechanism.

8. The apparatus of claim 1, further comprising:
a controllable bladder deflation mechanism couplable with said linearly inflating airflow baffle bladder.

9. The apparatus of claim 1, further comprising:
a linear bladder retraction mechanism couplable with said linearly inflating airflow baffle bladder.

10 through 16. (canceled)

17. A component attachment apparatus for a computer system, said apparatus comprising:
a linearly inflating airflow baffle bladder configured for expanding to fill a void within a computer system in response to being inflated into an inflated state;
a fixable surface of said inflatable bladder, said fixable surface fixedly couplable to a first interior surface of said computer system; and
a component attaching topologically self-adjusting compliant surface of said linearly inflating airflow baffle bladder, said component attaching topologically self-adjusting compliant surface configured for applying a linearly acting compressive force to fixedly couple a heat sink to a processor.

18. The apparatus of claim 17, wherein said inflatable bladder further comprises:
a first airflow baffle wall forming surface of said inflatable bladder, said first wall forming surface configured for forming a first side of a wall of a baffle for routing cooling air of said computer system through said heat sink;
a second airflow baffle wall forming surface configured for forming a second side of said wall;
a first air sealing surface configured for forming a first air seal with a second interior surface of said computer system; and
a second air sealing surface configured for forming a second air seal with a third interior surface of said computer system.

19. The apparatus of claim 17, further comprising:
an controllable bladder inflation mechanism configured for coupling with and inflating said linearly inflating airflow baffle bladder.

20. The apparatus of claim 17, further comprising:
a bladder shroud mechanism couplable with said linearly inflating airflow baffle bladder, said bladder shroud mechanism configured for controlling a direction of expansion of said linearly inflating airflow baffle bladder to prevent damage to an internal component of said computer system.
